(19) United States
(12) Patent Application Publication
(10) Pub. No.: US 2021/0408176 A1
(43) Pub. Date: Dec. 30, 2021

(54) ORGANIC LIGHT-EMITTING DISPLAY PANEL, MANUFACTURING METHOD THEREOF, AND ORGANIC LIGHT-EMITTING DISPLAY DEVICE

(71) Applicant: Shenzhen China Star Optoelectronics Semiconductor Display Technology Co., Ltd., Shenzhen, Guangdong (CN)

(72) Inventor: Yifei Bing, Shenzhen (CN)

(73) Assignee: Shenzhen China Star Optoelectronics Semiconductor Display Technology Co., Ltd., Shenzhen, Guangdong (CN)

(21) Appl. No.: 16/637,900

(22) PCT Filed: Jan. 14, 2020
(86) PCT No.: PCT/CN2020/071908

§ 371 Date: Feb. 10, 2020

(30) Foreign Application Priority Data
Dec. 23, 2019 (CN) 201911342522.9

(51) Int. Cl. H01L 27/32; H01L 51/00; H01L 51/50; H01L 51/56

(52) U.S. Cl. CPC H01L 27/3246; H01L 51/0005; H01L 51/5036; H01L 2251/558; H01L 51/56; H01L 2227/323; H01L 51/5072

(57) ABSTRACT

An organic light-emitting display panel, a manufacturing method thereof, and an organic light-emitting display device are provided. The organic light-emitting display panel includes a substrate, a plurality of anode electrodes, a pixel definition layer, an electron transport layer, and a cathode electrode. The pixel definition layer surrounds to form a plurality of array-distributed grooves, and the anode electrodes are disposed in the grooves one by one. The pixel definition layer includes first retaining walls, second retaining walls, and third retaining walls. At least one compartment is formed among a first organic light-emitting layer, a second organic light-emitting layer, and a third organic light-emitting layer disposed on the anode electrodes.

### FIELD OF INVENTION

The present disclosure relates to the field of display technologies, and more particularly, to an organic light-emitting display panel, a manufacturing method thereof, and an organic light-emitting display device.

### BACKGROUND OF INVENTION

Organic light-emitting (organic light-emitting diodes, OLEDs) display panels have advantages of low costs, wide viewing angles, high contrast, and bendability. They have obtained significant effects in applications of small and large sizes at present, and are continuously occupying the market share of liquid crystal display devices.

An OLED display panel comprises a substrate, and an anode electrode, an organic light-emitting layer, and a cathode electrode disposed on the substrate in sequence. At present, the most conventional manufacturing method of an organic light-emitting layer is vacuum thermal evaporation (VTE). That is, heating small organic materials in a vacuum chamber, making them sublimated or gasified into vapor, and then depositing on a substrate via through holes of a metal mask. However, due to size limitations of vacuum chambers and masks, the vacuum thermal evaporation method is limited when manufacturing an organic OLED display panel having a greater area.

Compared to vacuum thermal evaporation, inkjet printing has several important advantages. The main working principle thereof is injecting an ink on a specified position of a substrate from a tiny nozzle under control of a computer program, and forming a pre-designed pattern at last. The method can achieve 100% of material utilization, and can reduce process cycle time by adding the number of nozzles, so it is suitable for preparing a large sized OLED display panel. In addition, the inkjet printing method does not need a vacuum chamber, which has a lower manufacturing cost.

In general, a corresponding pixel definition layer is needed to form on a substrate to define an ink film forming area when manufacturing an OLED panel by inkjet printing. The pixel definition layer will be filled with specific inks after inkjet printing. However, because some pixel definition layers have a larger amount of ink when dripping the ink, ink mixing phenomenon will occur at junctions of the pixel definition layer, thereby causing pixels having offset and mixed luminescent colors, making the product yield decreased.

Technical problem: current technology has a problem of poor illumination caused by mixture of different color inks in adjacent pixel areas when forming an organic light-emitting layer by inkjet printing.

### SUMMARY OF INVENTION

An embodiment of the present disclosure provides an organic light-emitting display panel which comprises:

a substrate;

a plurality of anode electrodes and a pixel definition layer disposed on the substrate, wherein the pixel definition layer surrounds to form a plurality of array-distributed grooves, the anode electrodes are disposed in the grooves one by one, the grooves comprise a plurality of first grooves, a plurality of second grooves, and a plurality of third grooves, the pixel definition layer comprises first retaining walls, second retaining walls, and third retaining walls, the first grooves are disposed between the first retaining walls and the second retaining walls, the second grooves are disposed between the second retaining walls and the third retaining walls, and the third grooves are disposed between the third retaining walls and the first retaining walls;

an organic light-emitting layer disposed on the anode electrodes and comprising a first organic light-emitting layer, a second organic light-emitting layer, and a third organic light-emitting layer, wherein the first organic light-emitting layer is disposed in the first grooves, the second organic light-emitting layer is disposed in the second grooves, and the third organic light-emitting layer is disposed in the third grooves, wherein at least a compartment is formed among the first organic light-emitting layer, the second organic light-emitting layer, and the third organic light-emitting layer;

an electron transport layer covering the first organic light-emitting layer, the second organic light-emitting layer, the third organic light-emitting layer, the pixel definition layer, and the compartment; and

a cathode electrode covering the electron transport layer.

To achieve the above objective, an embodiment of the present disclosure further provides an organic light-emitting display device. The organic light-emitting display device comprises an integrated circuit and the above organic light-emitting display panel, wherein the integrated circuit is connected to the organic light-emitting display panel.

To achieve the above objective, an embodiment of the present disclosure further provides a manufacturing method of an organic light-emitting display panel. The method comprises:

providing a substrate;

disposing a plurality of anode electrodes and a pixel definition layer on the substrate, wherein the pixel definition layer surrounds to form a plurality of array-distributed grooves, the anode electrodes are disposed in the grooves one by one, the grooves comprise a plurality of first grooves, a plurality of second grooves, and a plurality of third grooves, the pixel definition layer comprises first retaining walls, second retaining walls, and third retaining walls, the first grooves are disposed between the first retaining walls and the second retaining walls, the second grooves are disposed between the second retaining walls and the third retaining walls, and the third grooves are disposed between the third retaining walls and the first retaining walls;

dripping an ink dissolved with a first organic light-emitting material to the first grooves and forming a first organic light-emitting layer, dripping an ink dissolved with a second organic light-emitting material to the second grooves and forming a second organic light-emitting layer, and dripping an ink dissolved with a third organic light-emitting material to the third grooves and forming a third organic light-emitting layer by inkjet printing, wherein at least a compartment is formed among the first organic light-emitting layer, the second organic light-emitting layer, and the third organic light-emitting layer;

forming an electron transport layer covering the first organic light-emitting layer, the second organic light-emitting layer, the third organic light-emitting layer, the pixel definition layer, and the compartment; and

forming a cathode electrode covering the electron transport layer.

Beneficial effect: the present disclosure disposes the pixel definition layer as first retaining walls, second retaining walls, and third retaining walls, and makes the pixel definition layer surrounds to form array-distributed first grooves, second grooves, and third grooves, wherein the first grooves are disposed between the first retaining walls and the second retaining walls, the second grooves are disposed between the second retaining walls and the third retaining walls, and the third grooves are disposed between the third retaining walls and the first retaining wall. Inks dissolved with organic light-emitting materials are dripped into the first grooves, the second grooves, and the third grooves to form an organic light-emitting layer. At least one compartment is formed among a first organic light-emitting layer, a second organic light-emitting layer, and a third organic light-emitting layer. Mixing of inks having different organic light-emitting materials between adjacent grooves is prevented by the blocking of the compartment, thereby preventing poor phenomenon of luminescent color offset and mixed luminescent colors of pixels in an OLED display panel.

### DESCRIPTION OF DRAWINGS

FIG. 1 is a schematic diagram of dripping inks to an organic light-emitting display panel by inkjet printing in current technology.

FIG. 2 is a schematic cross-sectional diagram of an organic light-emitting display panel manufactured by inkjet printing in current technology.

FIG. 3 is a schematic diagram of dripping inks to an organic light-emitting display panel by inkjet printing according to an embodiment of the present disclosure.

FIG. 4 is a schematic cross-sectional diagram of an organic light-emitting display panel according to an embodiment of the present disclosure.

FIG. 5 is a schematic diagram of dripping inks to an organic light-emitting display panel by inkjet printing according to another embodiment of the present disclosure.

FIG. 6 is a schematic cross-sectional diagram of an organic light-emitting display panel according to another embodiment of the present disclosure.

FIG. 7 is a flowchart of a manufacturing method of an organic light-emitting display panel according to an embodiment of the present disclosure.

### DETAILED DESCRIPTION OF PREFERRED EMBODIMENTS

In order to make the objectives, technical solutions, and advantages of the present disclosure clearer, the present disclosure is further described in detail below with reference to the accompanying drawings and embodiments. It should be understood that the specific embodiments described herein are only used to explain the disclosure, and are not used to limit the disclosure. In the case of no conflict, the following embodiments and their technical features can be combined with each other.

The specific embodiments described with reference to the attached drawings are all exemplary and are intended to illustrate and interpret the present disclosure. In the description of the present disclosure, it should be understood that terms such as “upper”, “lower”, “front”, “rear”, “left”, “right”, “inside”, “outside”, “side”, as well as derivative thereof should be construed to refer to the orientation as described or as shown in the drawings under discussion. These relative terms are for convenience of description, do not require that the present disclosure be constructed or operated in a particular orientation, and shall not be construed as causing limitations to the present disclosure. The identical or similar reference numerals constantly denote the identical or similar elements or elements having the identical or similar functions in the drawings.

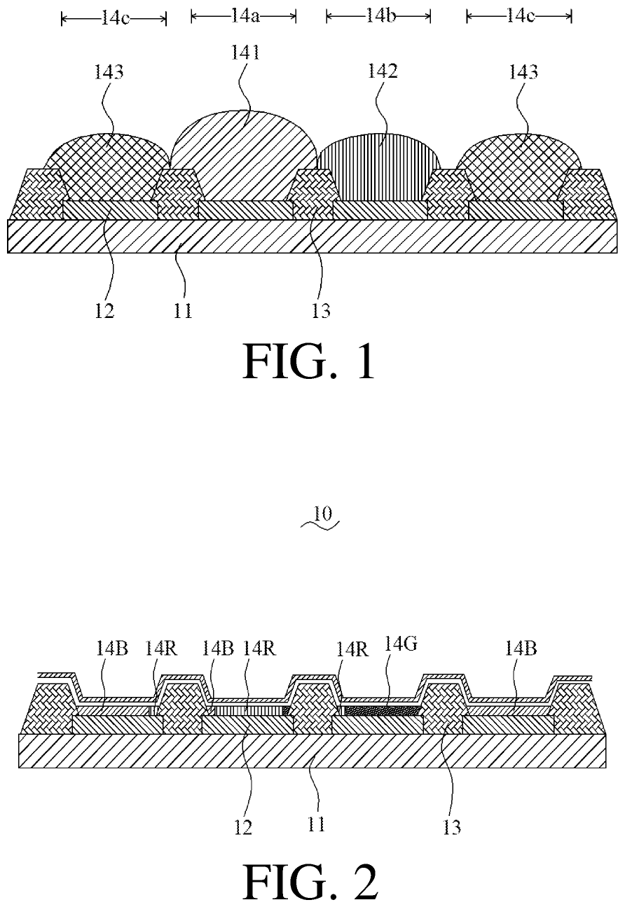

Referring to FIG. 1 and FIG. 2, FIG. 1 is a schematic diagram of dripping inks to an organic light-emitting display panel by inkjet printing in current technology, and FIG. 2 is a schematic cross-sectional diagram of an organic light-emitting display panel manufactured by inkjet printing in current technology.

First, it needs to manufacture anode electrodes (Anode) 12 and a pixel definition layer (PDL) 13 on a substrate 11. The pixel definition layer 13 is used to define array-distributed red pixel areas 14a, green pixel areas 14b, and blue pixel areas 14c, and then inks 141 142 143 dissolved with organic light-emitting materials are respectively filled in the red pixel areas 14a, the green pixel areas 14b, and the blue pixel areas 14c to form organic light-emitting layers which are used to emit red light, green light, and blue light. Wherein, the inks 141 142 143 have a lower concentration, in order to achieve a predetermined thickness of the organic light-emitting layers, the pixel definition layer 13 needs to accommodate enough amounts of inks. In addition, the organic light-emitting layers with different colors have different thicknesses. Specifically, an amount of an ink 141 dissolved with a red organic light-emitting material 141 R is greater than an amount of an ink 142 dissolved with a blue organic light-emitting material 142B, and is also greater than an amount of an ink 143 dissolved with a green organic light-emitting material 143G, thereby causing the inks to mix at junctions of pixel areas of the pixel definition layer 13. That is, the ink 141 dissolved with the red organic light-emitting material 141 R will mix with the ink 142 dissolved with the blue organic light-emitting material 142B and the ink 143 dissolved with the green organic light-emitting material 143G at the junctions of the pixel definition layer 13.

The ink mixing phenomenon will cause a pixel area of an OLED display panel 10 to include two or more colors of organic light-emitting materials simultaneously. As shown in FIG. 1 and FIG. 2, the blue pixel areas 14c include the blue organic light-emitting material 142B and the red organic light-emitting material 141R simultaneously, the red pixel areas 14a not only contain the red organic light-emitting material 141 R, but also are doped with the blue organic light-emitting material 142B and the green organic light-emitting material 143G at two terminals of the red organic light-emitting material 141R, and the green pixel areas 14b contain the green organic light-emitting material 143G and the red organic light-emitting material 141R simultaneously, thereby making the OLED display panel 10 have problems of poor illumination, such as luminescent color offset and mixed luminescent colors in pixels.

Therefore, it is necessary to provide an organic light-emitting display panel to solve the problem of poor illumination caused by mixture of different color inks in adjacent pixel areas when forming an organic light-emitting layer by inkjet printing.

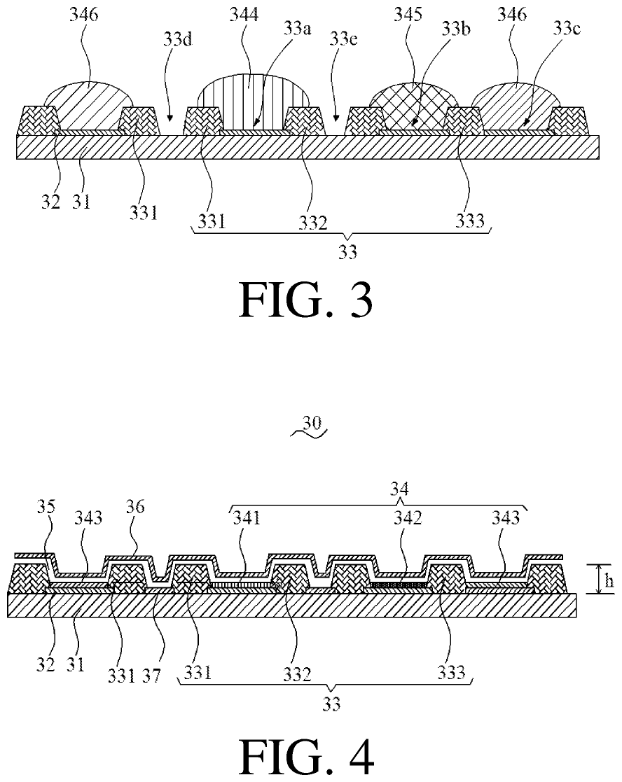

Referring to FIG. 3 and FIG. 4, which is an organic light-emitting display panel 30 provided by an embodiment of the present disclosure. The organic light-emitting display panel 30 comprises a substrate 31, anode electrodes 32, a pixel definition layer 33, an organic light-emitting layer 34, an electron transport layer 35, and a cathode electrode 36. Wherein, the substrate 31 is used to support every structural layer of the OLED display panel 30 and electronic components.

The substrate 31 may be a glass substrate, a plastic substrate, or a rigid substrate, which is not limited herein. For manufacturing an OLED display device, the substrate 31 can be a flexible substrate, such as a polyimide (PI) substrate.

A buffer layer can be disposed on the substrate 31. The buffer layer has a function of blocking water and oxygen, and main ingredients thereof comprise, but are not limited to, silicon nitride compounds (SiNₓ), silicon oxide compounds (SiOₓ), or silicon oxynitride (SiOₓN_{y}). When the buffer layer is disposed, every structural layer of the OLED display panel 30 and the electronic components, such as the anode electrodes 32 and the pixel definition layer 33, are disposed on the buffer layer.

The anode electrodes 32 and the pixel definition layer 33 are disposed on the substrate 31. Wherein, the pixel definition layer 33 surrounds to form a plurality of array-distributed grooves, the anode electrodes 32 are disposed in the grooves one by one, and the organic light-emitting layer 34 is also disposed in the grooves and covers the anode electrodes 32.

Wherein, the plurality of grooves comprise a plurality of first grooves 33a, a plurality of second grooves 33b, and a plurality of third grooves 33c. The first grooves 33a, the second grooves 33b, and the third grooves 33c are provided with the anode electrodes 32 and the organic light-emitting layer 34.

Further, the pixel definition layer 33 includes first retaining walls 331, second retaining walls 332, and third retaining walls 333. Wherein, a first groove 33a is disposed between a first retaining wall 331 and a second retaining wall 332, a second groove 33b is disposed between a second retaining wall 332 and a third retaining wall 333, and a third groove 33c is disposed between a third retaining wall 333 and a first retaining wall 331.

Wherein, the organic light-emitting layer 34 includes a first organic light-emitting layer 341, a second organic light-emitting layer 342, and a third organic light-emitting layer 343. In an embodiment of the present disclosure, wherein thicknesses of the second organic light-emitting layer 342 and the third organic light-emitting layer 343 are equal to each other, and are less than a thickness of the first organic light-emitting layer 341. The first organic light-emitting layer 341 is disposed in the first grooves 33a, the second organic light-emitting layer 342 is disposed in the second grooves 33b, and the third organic light-emitting layer 343 is disposed in the third grooves 33c. Wherein, the first organic light-emitting layer 341 is doped with a red organic light-emitting material, the second organic light-emitting layer 342 is doped with a green organic light-emitting material, and the third organic light-emitting layer 343 is doped with a blue organic light-emitting material. That is, an ink 344 doped with the red organic luminescent material forms the first organic light-emitting layer 341, an ink 345 doped with the green organic luminescent material forms the second organic light-emitting layer 342, and an ink 346 doped with the blue organic luminescent material forms the third organic light-emitting layer 343.

In the embodiment, take inkjet printing as an example to manufacturing the organic light-emitting layer. It should be understood that when dripping the inks which form the organic light-emitting layer, an amount of the ink 344 doped with the red organic luminescent material is greater than an amount of the ink 345 doped with the green organic luminescent material and an amount of the ink 346 doped with the blue organic luminescent material, thereby the ink 344 doped with the red organic luminescent material dripped into the first grooves 33a will be probably mixed with the ink 345 doped with the green organic luminescent material and the ink 346 doped with the blue organic luminescent material which are dripped into the second grooves 33b and the third grooves33c at two terminals of the first grooves 33a. Therefore, at least one compartment can be formed among the first organic light-emitting layer 341, the second organic light-emitting layer 342, and the third organic light-emitting layer 343. The phenomenon of the ink 344 doped with the red organic luminescent material mixing with the ink 345 doped with the green organic luminescent material and the ink 346 doped with the blue organic luminescent material at two terminals when the ink 344 has a larger amount, can be prevented by the blocking effect of the disposed compartment.

Specifically, in the embodiment, a first compartment 33d is formed between the first organic light-emitting layer 341 and the second organic light-emitting layer 342, and a second compartment 33e is formed between the first organic light-emitting layer 341 and the third organic light-emitting layer 343. That is, the first compartment 33d is disposed between two of the adjacent first retaining walls 331, and the second compartment 33e is disposed between two of the adjacent second retaining walls 332. The phenomenon of the ink 344 doped with the red organic luminescent material mixing with the ink 345 doped with the green organic luminescent material and the ink 346 doped with the blue organic luminescent material at two terminals when the ink 344 has a larger amount, can be prevented by the blocking of the compartment.

In addition, the thicknesses of the second organic light-emitting layer 342 and the third organic light-emitting layer 343 are the same, that is, dripping amounts of the ink 345 doped with the green organic luminescent material and the ink 346 doped with the blue organic luminescent material are the same, so the compartment may be not disposed between the second grooves 33b and the third grooves 33c, and only be disposed at two terminals of the first grooves 33a.

In the embodiment, because compartments are disposed among the organic light-emitting layers, the first retaining walls 331, the second retaining walls 332, and the third retaining walls 333 can be set with a same height h. That way, a mixing phenomenon of inks dripped into the adjacent pixel definition layers can be prevented.

In other embodiment, the first retaining walls 331, the second retaining walls 332, and the third retaining walls 333 can be set with different heights, or the first retaining walls 331 and the second retaining walls 332 have a same height, but have a different height with the third retaining walls 333. When the first retaining walls 331 and the second retaining walls 332 have the same height, but have a different height with the third retaining walls 333, in order to prevent ink mixing phenomenon more effectively, the height of the third retaining walls 333 can be set greater than the height of the first retaining walls 331 and the second retaining walls 332, thereby preventing the ink 345 doped with the green organic luminescent material in the second grooves 33b to mix with the ink 346 doped with the blue organic luminescent material in the third grooves 33c at two terminals of the third retaining walls 333.

Further, in order to facilitate dripping of inks to form the organic light-emitting layer 34, two corresponding sides of the first retaining walls 331, the second retaining walls 332, and the third retaining walls 333 are inclined relative to the substrate 31, thereby making it difficult to overflow when dripping the inks.

In addition, tilt angles θ of the first retaining walls 331, the second retaining walls 332, and the third retaining walls 333 are the same, thereby when forming the pixel definition layer, the productive cost can be saved and the process time can be reduced by using a same mask for etching process.

Further, the compartments can be formed between the adjacent first retaining walls 331 and between the adjacent second retaining walls 332 to prevent ink mixing. Therefore, in the embodiment, widths of the first grooves 33a, the second grooves 33b, and the third grooves 33c are greater than widths of the first compartment 33d and the second compartment 33e. In other embodiment, the widths of the first grooves 33a, the second grooves 33b, and the third grooves 33c can be set equal to the widths of the first compartment 33d and the second compartment 33e, thereby preventing mixing of inks in different grooves more effectively.

In an embodiment of the present disclosure, a surface of the substrate 31 may be hydrophilic, and surfaces of the first retaining walls 331, the second retaining walls 332, and the third retaining walls 333 are hydrophobic. Therefore, the inks 344 345 346 are not easy to overflow the corresponding retaining walls, and are easier to flow to the substrate 31, thereby preventing the inks dissolved with different organic light-emitting materials to mix with each other through the first retaining walls 331 and the second retaining walls 332, and further preventing pixels of the OLED display panel 30 to have poor illumination.

In addition, after forming the compartment, to prevent light leaking from the compartment, to increase conductivity of an cathode of the panel, to decrease resistance of the cathode, and to improve uniformity of illumination, a cathode layer 37 is disposed in the compartment and on a surface of the electron transport layer 35 away from the cathode electrode 36. Wherein, main materials of the cathode layer 37 are metal materials, such as Ag, Al, Li, Mg, and Ca.

The electron transport layer 35 in the embodiment covers the first organic light-emitting layer 341, the second organic light-emitting layer 342, the third organic light-emitting layer 343, the pixel definition layer 13, and the cathode layer 37 in the first compartment 33d and the second compartment 33e.

Further, the cathode electrode 36 covers the electron transport layer 35, and the OLED display panel 30 is obtained thereby. Wherein, a preparing material of the cathode electrode 36 in the embodiment is a metal material, which can be the same or different with the material of the cathode layer 37. The resistance of the cathode can be reduced, the uniformity of illumination can be improved, and the luminous performance of products can be further improved by disposing a layer of the cathode layer 37 in the compartments 33d 33e, and then disposing the electron transport layer 35 and the cathode electrode 36 on whole surface.

It should be understood that the OLED display panel 30 further comprises a hole injection layer (HIL), a hole transport layer (HTL), and an electron injection layer (EIL). The hole injection layer is disposed on the anode electrodes 32, the hole transport layer is disposed between the hole injection layer and the organic light-emitting layer, and the electron injection layer is disposed between the electron transport layer 35 and the cathode electrode 36.

The above organic light-emitting display panel 30 disposes the pixel definition layer 33 as the first retaining walls 331, the second retaining walls 332, and the third retaining walls 333, and makes the pixel definition layer 33 surrounds to form array-distributed first grooves 33a, second grooves 33b, and third grooves 33c, wherein the first grooves 33a are disposed between the first retaining walls 331 and the second retaining walls 332, the second grooves 33b are disposed between the second retaining walls 332 and the third retaining walls 333, and the third grooves 33c are disposed between the third retaining walls 333 and the first retaining walls 331. Inks dissolved with organic light-emitting materials are dripped into the first grooves 33a, the second grooves 33b, and the third grooves 33c to form the organic light-emitting layer 34. The organic light-emitting layer 34 includes the first organic light-emitting layer 341, the second organic light-emitting layer 342, and the third organic light-emitting layer 343. The first compartment 33d is formed between the first organic light-emitting layer 341 and the second organic light-emitting layer 342, and the second compartment 33e is formed between the first organic light-emitting layer 341 and the third organic light-emitting layer 343. Mixing of inks having different organic light-emitting materials between adjacent grooves is prevented by the blocking of the compartment, thereby preventing poor phenomenon of luminescent color offset and mixed luminescent colors of pixels in an OLED display panel.

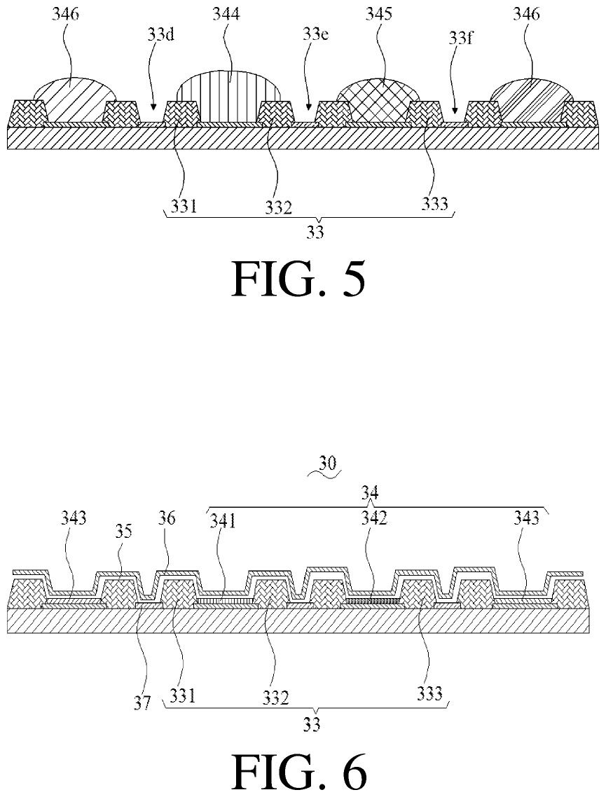

Referring to FIG. 5 and FIG. 6, which are another OLED display panel 30 in another embodiment of the present disclosure, the OLED display panel 30 of the embodiment is basically similar to the organic light-emitting display panel 30 in embodiment 1. The difference is that a third compartment 33f is formed between the second organic light-emitting layer 342 and the third organic light-emitting layer 343. That is, the third compartment 33f is formed between the adjacent third retaining walls 333.

That way, the first compartment 33d is disposed between the adjacent first retaining walls 331, the second compartment 33e is disposed between the adjacent second retaining walls 332, and the third compartment 33f is disposed between the adjacent third retaining walls 333. That is, the compartments are disposed at both sides of each groove, thereby preventing the dripped inks to mix with each other in adjacent grooves more effectively.

Further, the widths of the first grooves 33a, the second grooves 33b, and the third grooves 33c are all greater than a width of the third compartment 33f. In addition, in the embodiment, the widths of the first compartment 33d, the second compartment 33e, and the third compartment 33f are the same. In other embodiments, the widths of the first compartment 33d and the second compartment 33e can be set to be greater than the width of the third compartment 33f. Because the first grooves 33a are disposed between the first retaining walls 331 and the second retaining walls 332, and the first grooves 33a are used to dripping the ink 344 dissolved with the red organic light-emitting material and having a larger amount, when the compartments at two sides of the first grooves 33a are larger, the phenomenon of the ink 344 dissolved with the red organic light-emitting material mixing with the ink 345 dissolved with the green organic light-emitting material and the ink 346 dissolved with the blue organic light-emitting material at the two sides can be prevented more effectively.

The above organic light-emitting display panel 30 disposes the third compartment 33f between the second organic light-emitting layer 342 and the third organic light-emitting layer 343, so the compartments are disposed at both sides of each groove, thereby preventing the ink 344 dissolved with the red organic light-emitting material, the ink 345 dissolved with the green organic light-emitting material, and the ink 346 dissolved with the blue organic light-emitting material to mix with the inks at both sides, thereby preventing poor phenomenon of luminescent color offset and mixed luminescent colors of pixels in the OLED display panel.

An embodiment of the present disclosure further provides an OLED display device. The OLED display device comprises an integrated circuit (IC) and an OLED display panel connected to the integrated circuit, wherein the OLED display panel may comprise a same structure with any one of the OLED display panels 30 in the above embodiments. Therefore, the OLED display device can achieve forming compartments at both sides of the first grooves 33a, the second grooves 33b, and the third grooves 33c by forming a first compartment 33d between the first organic light-emitting layer 341 and the second organic light-emitting layer 342, forming a second compartment 33e between the first organic light-emitting layer 341 and the third organic light-emitting layer 343, and forming a third compartment between the second organic light-emitting layer 342 and the third organic light-emitting layer 343, thereby effectively preventing a dripped ink in the grooves to mix with an ink in the adjacent grooves and further preventing poor phenomenon of luminescent color offset and mixed luminescent colors of pixels in the OLED display panel 30.

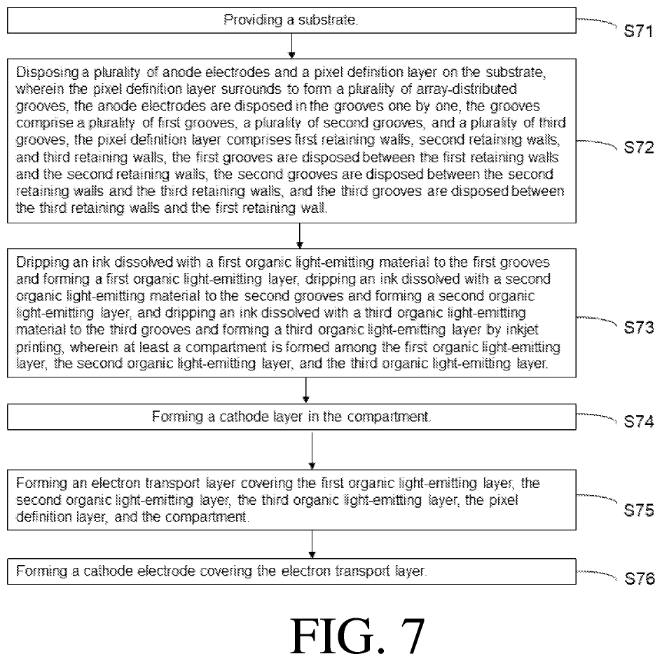

Referring to FIG. 7, FIG. 7 is a flowchart of a manufacturing method of an OLED display panel according to an embodiment of the present disclosure. The manufacturing method of the OLED display panel comprises step S71 to step S76.

Step S71: providing a substrate.

Wherein, the substrate is used to support every structural layer of the OLED display panel and electronic components. The substrate may be a glass substrate, a plastic substrate, or a rigid substrate, which is not limited herein. For manufacturing an OLED display device, the substrate can be a flexible substrate, such as a polyimide (PI) substrate.

A buffer layer can be disposed on the substrate. The buffer layer has a function of blocking water and oxygen, and main ingredients thereof comprise, but are not limited to, silicon nitride compounds (SiNₓ), silicon oxide compounds (SiOₓ), or silicon oxynitride (SiOₓN_{y}). When the buffer layer is disposed, every structural layer of the OLED display panel and the electronic components, such as anode electrodes and pixel definition layer, are disposed on the buffer layer.

Step S72: disposing a plurality of anode electrodes and a pixel definition layer on the substrate, wherein the pixel definition layer surrounds to form a plurality of array-distributed grooves, the anode electrodes are disposed in the grooves one by one, the grooves comprise a plurality of first grooves, a plurality of second grooves, and a plurality of third grooves, the pixel definition layer comprises first retaining walls, second retaining walls, and third retaining walls, the first grooves are disposed between the first retaining walls and the second retaining walls, the second grooves are disposed between the second retaining walls and the third retaining walls, and the third grooves are disposed between the third retaining walls and the first retaining wall.

In the embodiment, the anode electrodes can be formed first, then forming the pixel definition layer. For example, the anode electrodes and the pixel definition layer can be manufactured respectively by a mask etching process, which includes film forming, exposing, developing, and etching.

Specifically, the step of forming the anode electrodes by the mask etching process comprises:

first, forming a whole surface of conductive layer and a photoresist layer covering the conductive layer on the substrate. The conductive layer may use a material having good conductivity and corrosion resistance, such as metal materials, which comprises, but is not limited to, molybdenum, nickel, palladium, cobalt, tungsten, rhodium, titanium, chromium, gold, silver, and platinum. In addition, to further improve the conductivity, the conductive layer may be a multi-layered metal structure, such as a three-layered metal structure of molybdenum/aluminum/molybdenum, a three-layered metal structure of nickel/copper/nickel, a three-layered metal structure of molybdenum/copper/molybdenum, or a three-layered metal structure of nickel/aluminum/nickel. It not only can improve conductivity of the conductive layer and anode electrodes prepared from the conductive layer, but also can improve the corrosion resistance of the conductive layer and the anode electrodes by disposing three-layered metal conductive structures.

Then using a mask to expose the photoresist layer to obtain a photoresist layer having a predetermined pattern, wherein the photoresist layer having the predetermined pattern exposes a part of the conductive layer to be etched. Specifically, the mask is provided with a light transmission area. In the exposing process, the mask is disposed on the photoresist layer at an interval, a pattern of the light transmission area is in consistent with the pattern to be etched, light exposes the photoresist layer through the light transmission area, the exposed part of the photoresist layer is removed by a developer, and the unexposed part of the photoresist layer cannot be removed by the developer and is retained. In a top view, the photoresist layer is transformed into the photoresist layer having the predetermined pattern, wherein a part of the photoresist layer removed by the developer exposes the part of the conductive layer to be etched.

Then etching to remove a part of the conductive layer which is not covered by the photoresist layer. The embodiment can remove the part of the conductive layer which is not covered by the photoresist layer by a dry etching process or a wet etching process. Take the wet etching process for example, the part of the conductive layer which is not covered by the photoresist layer is in full contact with an etching solution, reacts to dissolve, and is completely removed. The part of the conductive layer which is covered by the photoresist layer is not in contact with the etching solution and can be retained, so the conductive layer is etched into the anode electrodes with the predetermined pattern.

At last, ashing to remove the photoresist layer to obtain the anode electrodes.

The manufacturing process and principle of the pixel definition layer by the mask etching process can refer to the above description, which is not repeated herein. In addition, the pixel definition layer also can be manufactured with a mask and by other film forming processes, such as physical vapor deposition (PVD), pulsed laser deposition (PLD), or magnetron sputtering.

In the embodiment, the pixel definition layer surrounds to form a plurality of array-distributed grooves, each anode electrode is disposed in each groove, and the grooves are used to define pixel areas of the OLED display panel. Take the pixel areas comprising red pixel areas, green pixel areas, and blue pixel areas for example, the grooves can be divided into first grooves which are used to define the red pixel areas, second grooves which are used to define the green pixel areas, and third grooves which are used to define the blue pixel areas.

The pixel definition layer can be divided into first retaining walls, second retaining walls, and third retaining walls, wherein the first grooves are disposed between the first retaining walls and the second retaining walls, the second grooves are disposed between the second retaining walls and the third retaining walls, and the third grooves are disposed between the third retaining walls and the first retaining walls.

Step S73: dripping an ink dissolved with a first organic light-emitting material to the first grooves and forming a first organic light-emitting layer, dripping an ink dissolved with a second organic light-emitting material to the second grooves and forming a second organic light-emitting layer, and dripping an ink dissolved with a third organic light-emitting material to the third grooves and forming a third organic light-emitting layer by inkjet printing, wherein at least a compartment is formed among the first organic light-emitting layer, the second organic light-emitting layer, and the third organic light-emitting layer.

The first organic light-emitting material is used to emit red light, the second organic light-emitting material is used to emit green light, and the third organic light-emitting material is used to emit blue light. The embodiment of the present disclosure can respectively drip the ink dissolved with the first organic light-emitting material, the ink dissolved with the second organic light-emitting material, and the ink dissolved with the third organic light-emitting material into the first grooves, the second grooves, and the third grooves, or can respectively drip the inks dissolved with organic light-emitting materials into three grooves at a predetermined order. For example, the ink dissolved with the first organic light-emitting material can be dripped into the first grooves first, then the ink dissolved with the second organic light-emitting material is dripped into the second grooves, and at last the ink dissolved with the third organic light-emitting material is dripped into the third grooves.

The embodiment of the present disclosure further drips the inks in the grooves to make the ink dissolved with the first organic light-emitting material form the first organic light-emitting layer, make the ink dissolved with the second organic light-emitting material form the second organic light-emitting layer, and make the ink dissolved with the third organic light-emitting material form the third organic light-emitting layer. The first organic light-emitting layer, the second organic light-emitting layer, and the third organic light-emitting layer form the organic light-emitting layer of the OLED display panel. Wherein, thicknesses of the second organic light-emitting layer and the third organic light-emitting layer are equal to each other and less than a thickness of the first organic light-emitting layer. It should be understood that the dripped amount of ink doped with the green organic light-emitting material and the dripped amount of ink doped with the blue organic light-emitting material are less than the dripped amount of ink doped with the red organic light-emitting material.

All the grooves are dripped with the inks which are dried to form a film of the organic light-emitting layer, and the inks will mix with each other on the pixel definition layer at junctions of pixel areas before forming the film, so at least one compartment is formed among the first organic light-emitting layer, the second organic light-emitting layer, and the third organic light-emitting layer, thereby with blocking of the compartment, the ink mixing phenomenon can be prevented.

In the embodiment, compartments are formed between the first organic light-emitting layer and the second organic light-emitting layer, between the first organic light-emitting layer and the third organic light-emitting layer, and between the second organic light-emitting layer and the third organic light-emitting layer. A second compartment is formed between the first organic light-emitting layer and the third organic light-emitting layer, a first compartment is formed between the first organic light-emitting layer and the second organic light-emitting layer, and a third compartment is formed between the second organic light-emitting layer and the third organic light-emitting layer, thereby with the blocking of each compartment, the phenomenon of the dripped ink in each groove mixing with the inks of the adjacent grooves can be prevented.

Step S74: forming a cathode layer in the compartment.

After forming the compartment, to prevent light leaking from the compartment, to increase conductivity of an cathode of the panel, to decrease resistance of the cathode, and to improve uniformity of illumination, a cathode layer is disposed in the compartment, wherein the main material of the cathode layer is a metal material, such as Ag, Al, Li, Mg, and Ca.

Step S75: forming an electron transport layer covering the first organic light-emitting layer, the second organic light-emitting layer, the third organic light-emitting layer, the pixel definition layer, and the compartment.

Wherein, the electron transport layer can decrease a potential barrier of injecting electrons from the cathode electrode, which makes the electrons effectively injected to an OLED device from the cathode electrode, and can decrease a potential barrier of injecting holes from the anode, which makes the holes effectively injected to the OLED device from the anode. The main material for preparing the electron transport layer may comprise LiF, MgP, MgF₂, or Al₂O₃.

Step S76: forming a cathode electrode covering the electron transport layer.

The embodiment of the present disclosure can form the electron transport layer (ETL) and the cathode electrode (Cathode) in sequence by film forming processes, such as PVD, PLD, or sputtering.

It should be understood that all structural parts of the OLED display panel have not been made in the above processes. For example, the OLED display panel further comprises a hole injection layer (HIL), a hole transport layer (HTL), and an electron injection layer (EIL). The hole injection layer is disposed on the anode electrodes, the hole transport layer is disposed between the hole injection layer and the organic light-emitting layer, and the electron injection layer is disposed between the electron transport layer and the cathode electrode. Manufacturing processes of these undescribed structural parts can refer to the current technology.

The OLED display panel can be obtained according to the above steps S71 to S76.

The above manufacturing method of the OLED display panel disposes the pixel definition layer as the first retaining walls, the second retaining walls, and the third retaining walls, and makes the pixel definition layer surrounds to form array-distributed first grooves, second grooves, and third grooves, wherein the first grooves are disposed between the first retaining walls and the second retaining walls, the second grooves are disposed between the second retaining walls and the third retaining walls, and the third grooves are disposed between the third retaining walls and the first retaining walls. Inks dissolved with organic light-emitting materials are dripped into the first grooves, the second grooves, and the third grooves to form the organic light-emitting layer. The first compartment is formed between the first organic light-emitting layer and the second organic light-emitting layer, the second compartment is formed between the first organic light-emitting layer and the third organic light-emitting layer, and the third compartment is formed between the second organic light-emitting layer and the third organic light-emitting layer. Mixing of inks dissolved with different organic light-emitting materials is prevented by the blocking of the compartments, thereby preventing poor phenomenon of luminescent color offset and mixed luminescent colors of pixels in the OLED display panel.

The above-mentioned embodiments only express several implementations of the present disclosure, and the description thereof is more specific and detailed, but cannot be understood as a limitation on the scope of the present disclosure. It should be noted that for those having ordinary skills in the art, without departing from the concept of the present disclosure, several modifications and improvements can be made, and these all belong to the protection scope of the present disclosure. Therefore, the protection scope of the present disclosure shall be subject to the appended claims.

What is claimed is:

1. An organic light-emitting display panel, comprising:
a substrate;
a plurality of anode electrodes and a pixel definition layer disposed on the substrate, wherein the pixel definition layer surrounds to form a plurality of array-distributed grooves, the anode electrodes are disposed in the grooves one by one, the grooves comprise a plurality of first grooves, a plurality of second grooves, and a plurality of third grooves, the pixel definition layer comprises first retaining walls, second retaining walls, and third retaining walls, the first grooves are disposed between the first retaining walls and the second retaining walls, the second grooves are disposed between the second retaining walls and the third retaining walls, and the third grooves are disposed between the third retaining walls and the first retaining walls;
an organic light-emitting layer disposed on the anode electrodes and comprising a first organic light-emitting layer, a second organic light-emitting layer, and a third organic light-emitting layer, wherein the first organic light-emitting layer is disposed in the first grooves, the second organic light-emitting layer is disposed in the second grooves, and the third organic light-emitting layer is disposed in the third grooves, wherein at least a compartment is formed among the first organic light-emitting layer, the second organic light-emitting layer, and the third organic light-emitting layer;
an electron transport layer covering the first organic light-emitting layer, the second organic light-emitting layer, the third organic light-emitting layer, the pixel definition layer, and the compartment; and
a cathode electrode covering the electron transport layer.

2. The organic light-emitting display panel according to claim 1, wherein thicknesses of the second organic light-emitting layer and the third organic light-emitting layer are equal to each other and less than a thickness of the first organic light-emitting layer, and the compartments are formed between the first organic light-emitting layer and the second organic light-emitting layer and between the first organic light-emitting layer and the third organic light-emitting layer.

3. The organic light-emitting display panel according to claim 1, wherein a cathode layer is disposed in the compartment and on a surface of the electron transport layer away from the cathode electrode.

4. The organic light-emitting display panel according to claim 1, wherein a surface of the substrate is hydrophilic, and surfaces of the first retaining walls, the second retaining walls, and the third retaining walls are hydrophobic.

5. The organic light-emitting display panel according to claim 1, wherein widths of the first grooves, the second grooves, and the third grooves are greater than a width of the compartment.

6. An organic light-emitting display device, comprising an integrated circuit and an organic light-emitting display panel, wherein the integrated circuit is connected to the organic light-emitting display panel, and the organic light-emitting display panel comprises:
a substrate;
a plurality of anode electrodes and a pixel definition layer disposed on the substrate, wherein the pixel definition layer surrounds to form a plurality of array-distributed grooves, the anode electrodes are disposed in the grooves one by one, the grooves comprise a plurality of first grooves, a plurality of second grooves, and a plurality of third grooves, the pixel definition layer comprises first retaining walls, second retaining walls, and third retaining walls, the first grooves are disposed between the first retaining walls and the second retaining walls, the second grooves are disposed between the second retaining walls and the third retaining walls, and the third grooves are disposed between the third retaining walls and the first retaining walls;
an organic light-emitting layer disposed on the anode electrodes and comprising a first organic light-emitting layer, a second organic light-emitting layer, and a third organic light-emitting layer, wherein the first organic light-emitting layer is disposed in the first grooves, the second organic light-emitting layer is disposed in the second grooves, and the third organic light-emitting layer is disposed in the third grooves, wherein at least a compartment is formed among the first organic light-emitting layer, the second organic light-emitting layer, and the third organic light-emitting layer;
an electron transport layer covering the first organic light-emitting layer, the second organic light-emitting layer, the third organic light-emitting layer, the pixel definition layer, and the compartment; and
a cathode electrode covering the electron transport layer.

7. The organic light-emitting display device according to claim 6, wherein thicknesses of the second organic light-emitting layer and the third organic light-emitting layer are equal to each other and less than a thickness of the first organic light-emitting layer, and the compartments are formed between the first organic light-emitting layer and the second organic light-emitting layer and between the first organic light-emitting layer and the third organic light-emitting layer.

8. The organic light-emitting display device according to claim 6, wherein a cathode layer is disposed in the compartment and on a surface of the electron transport layer away from the cathode electrode.

9. The organic light-emitting display device according to claim 6, wherein a surface of the substrate is hydrophilic, and surfaces of the first retaining walls, the second retaining walls, and the third retaining walls are hydrophobic.

10. The organic light-emitting display device according to claim 6, wherein widths of the first grooves, the second grooves, and the third grooves are greater than a width of the compartment.

11. A manufacturing method of an organic light-emitting display panel, comprising:
providing a substrate;
disposing a plurality of anode electrodes and a pixel definition layer on the substrate, wherein the pixel definition layer surrounds to form a plurality of array-distributed grooves, the anode electrodes are disposed in the grooves one by one, the grooves comprise a plurality of first grooves, a plurality of second grooves, and a plurality of third grooves, the pixel definition layer comprises first retaining walls, second retaining walls, and third retaining walls, the first grooves are disposed between the first retaining walls and the second retaining walls, the second grooves are disposed between the second retaining walls and the third retaining walls, and the third grooves are disposed between the third retaining walls and the first retaining walls;
dripping an ink dissolved with a first organic light-emitting material to the first grooves and forming a first organic light-emitting layer, dripping an ink dissolved with a second organic light-emitting material to the second grooves and forming a second organic light-emitting layer, and dripping an ink dissolved with a third organic light-emitting material to the third grooves and forming a third organic light-emitting layer by inkjet printing, wherein at least a compartment is formed among the first organic light-emitting layer, the second organic light-emitting layer, and the third organic light-emitting layer;
forming an electron transport layer covering the first organic light-emitting layer, the second organic light-emitting layer, the third organic light-emitting layer, the pixel definition layer, and the compartment; and
forming a cathode electrode covering the electron transport layer.

12. The manufacturing method of the organic light-emitting display panel according to claim 11, wherein thicknesses of the second organic light-emitting layer and the third organic light-emitting layer are equal to each other and less than a thickness of the first organic light-emitting layer, and the compartments are formed between the first organic light-emitting layer and the second organic light-emitting layer and between the first organic light-emitting layer and the third organic light-emitting layer.

13. The manufacturing method of the organic light-emitting display panel according to claim 11, wherein before forming the electron transport layer, the method comprises:
forming a cathode layer in the compartment.

14. The manufacturing method of the organic light-emitting display panel according to claim 13, wherein a surface of the substrate is hydrophilic, and surfaces of the first retaining walls, the second retaining walls, and the third retaining walls are hydrophobic.

15. The manufacturing method of the organic light-emitting display panel according to claim 11, wherein widths of the first grooves, the second grooves, and the third grooves are greater than a width of the compartment.
